(19) United States
(12) Patent Application Publication
(10) Pub. No.: US 2007/0012919 A1
(43) Pub. Date: Jan. 18, 2007

(54) Thin film transistor substrate and method for fabricating the same

(76) Inventors: Min-seok Oh, Yongin-si (KR); Byoung-june Kim, Seongnam-si (KR); Sang-gab Kim, Seoul (KR); Sung-hoon Yang, Seoul (KR); Hong-kee Chin, Suwon-si (KR); Kunal Girotra, Yongin-si (KR)

Correspondence Address: MACPHERSON KWOK CHEN & HEID LLP, 2033 GATEWAY PLACE, SUITE 400, SAN JOSE, CA, 95110, US

(21) Appl. No.: 11/487,090

(22) Filed: Jul. 15, 2006

(30) Foreign Application Priority Data
Jul. 15, 2005 (KR) 10-2005-0064479

(51) Int. Cl. H01L 29/04

(52) U.S. Cl. 257/59

(57) ABSTRACT

Provided are a thin film transistor (TFT) substrate and a method for manufacturing the same. The method comprises forming on a substrate a conductive layer, an impurity-doped silicon layer, and an intermediate layer, wherein the intermediate layer comprises intrinsic silicon; patterning the intermediate layer, the impurity-doped silicon layer, and the conductive layer to form a data line, a source electrode, a drain electrode, ohmic contact portions, and intermediate portions, wherein an ohmic contact portion and an intermediate portion are on the source electrode, and an ohmic contact portion and an intermediate portion are on the drain electrode; forming an intrinsic silicon layer on the substrate; and patterning the intrinsic silicon layer to form a semiconductor layer forming channel portion between the source electrode and the drain electrode, and a contact portion on the intermediate portion.

### BACKGROUND OF THE INVENTION

This application claims priority from Korean Patent Application No. 10-2005-0064479, filed on Jul. 15, 2005, in the Korean Intellectual Property Office, the disclosure of which is incorporated by reference in its entirety.

1. Field of the Invention

The present invention relates to a thin film transistor (TFT) substrate and a method for fabricating the same, and more particularly, to a TFT substrate having improved electrical characteristics and stability, and a method for fabricating the same.

2. Description of the Related Art

A thin film transistor (TFT) substrate is used as a substrate for a liquid crystal display (LCD) having pixels in a matrix form and an organic electro luminescence (EL) display.

A liquid crystal display (“LCD”), which is one of the most widely used flat panel displays, includes two substrates having a plurality of electrodes and a liquid crystal layer interposed therebetween. In the LCD, thin film transistors are used as switching elements for controlling picture signals applied to the respective electrodes.

An organic EL display displays a picture by electrically exciting phosphorescent organic material, and includes a switching TFT and a driving TFT for supplying pixels with current necessary for light emission. Unlike the LCD, the organic EL display device is a self-emission display capable of achieving a wide viewing angle and a high response speed, and is regarded as a promising candidate for next generation displays.

However, to date, it has not been easy to design organic EL displays having a large display area. This is because large organic EL displays suffer from shortened lifespans due to instability of the constituent TFT's. The stability of a TFT is closely related to the electrical characteristics of the channel portion of the TFT. To maintain stability, the electrical conductivity in the channel portion should be high, and the threshold voltage shift in the channel portion should be low. To satisfy these conditions, the channel portion of the TFT can be formed from crystalline silicon having superior electrical characteristics, and an ohmic contact layer for reducing contact resistance can be interposed between the source/drain electrodes and the semiconductor layer. However, since the ohmic contact layer is patterned along with the source electrode and the drain electrode and the semiconductor layer is then deposited on the patterned ohmic contact layer, the top surface of the ohmic contact layer may be exposed to air, etchant or PR stripper in a subsequent process for a long time, allowing undesired foreign substances to settle on the surface. The foreign substances may increase the contact resistance, degrading TFT stability.

### SUMMARY OF THE INVENTION

The present invention provides a thin film transistor (TFT) substrate having improved electrical characteristics and improved stability, and a method for manufacturing the same.

The present invention also provides a TFT substrate manufactured using the method.

The above as well as other, features and advantages, of the present invention will become clear to those skilled in the art upon review of the following description.

According to an aspect of the present invention, there is provided a method for manufacturing a thin film transistor (TFT) substrate. The method comprises forming on a substrate a conductive layer, an impurity-doped silicon layer, and an intermediate layer, wherein the intermediate layer comprises intrinsic silicon; patterning the intermediate layer, the impurity-doped silicon layer, and the conductive layer to form a data line, a source electrode, a drain electrode, ohmic contact portions, and intermediate portions, wherein an ohmic contact portion and an intermediate portion are on the source electrode, and an ohmic contact portion and an intermediate portion are on the drain electrode; forming an intrinsic silicon layer on the substrate; and patterning the intrinsic silicon layer to form a semiconductor layer forming channel portion between the source electrode and the drain electrode, and a contact portion on the intermediate portion

According to another aspect of the present invention, there is provided a thin film transistor (TFT) substrate which comprises data lines including a source electrode formed on a substrate and a drain electrode separated from the source electrode; an ohmic contact layer formed on the source electrode and the drain electrode, wherein the ohmic contact layer comprises impurity-doped silicon; an intermediate layer formed on the ohmic contact layer, wherein the intermediate layer includes intrinsic silicon; and a semiconductor layer comprising a portion on the intermediate layer and a channel portion between the source electrode and the drain electrode.

### BRIEF DESCRIPTION OF THE DRAWINGS

The above and other features and advantages of the present invention will become more apparent by describing in detail exemplary embodiments thereof with reference to the attached drawings in which:

FIG. 1A is a layout view of a thin film transistor (TFT) substrate according to an embodiment of the present invention;

FIGS. 1B and 1C are sectional views cut along a line B-B′ and a line C-C′ of FIG. 1A;

FIGS. 2A, 3A, 4A, 5A, 6A, and 7A are layout views sequentially showing a method for manufacturing a TFT substrate according to an embodiment of the present invention;

FIGS. 2B, 3B, 4B, 5B, 6B, and 7B are sectional views cut along a line B-B′ of FIG. 2A, 3A, 4A, 5A, 6A, and 7A;

FIGS. 2C, 3C, 4C, 5C, 6C, and 7C are sectional views cut along a line C-C′ of FIG. 2A, 3A, 4A, 5A, 6A, and 7A;

FIG. 8A is a layout view of a TFT substrate according to another embodiment of the present invention; and

FIG. 8B is a sectional view cut along a line B-B′ of FIG. 8A.

### DETAILED DESCRIPTION OF THE INVENTION

The present invention will now be described more fully with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the concept of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It is noted that the use of any and all examples, or exemplary terms provided herein is intended merely to better illuminate the invention and is not a limitation on the scope of the invention unless otherwise specified. The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

The term “thin film transistor substrate” used herein refers to a substrate comprising at least one thin film transistor, and also covers other structures formed between the thin film transistor and the substrate, or other structures formed on the thin film transistor.

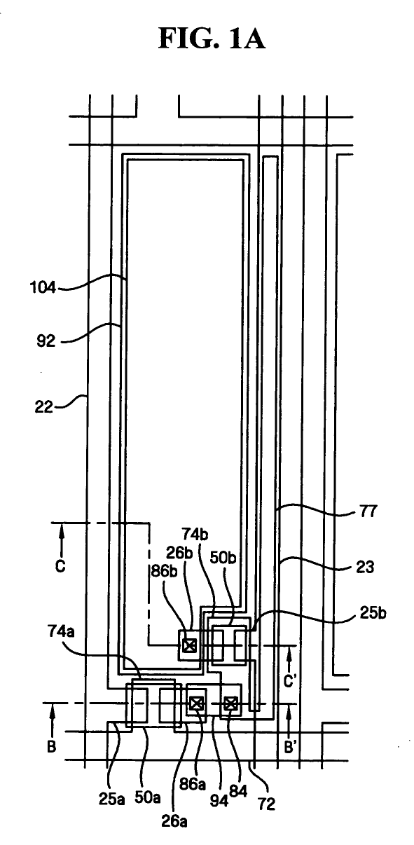

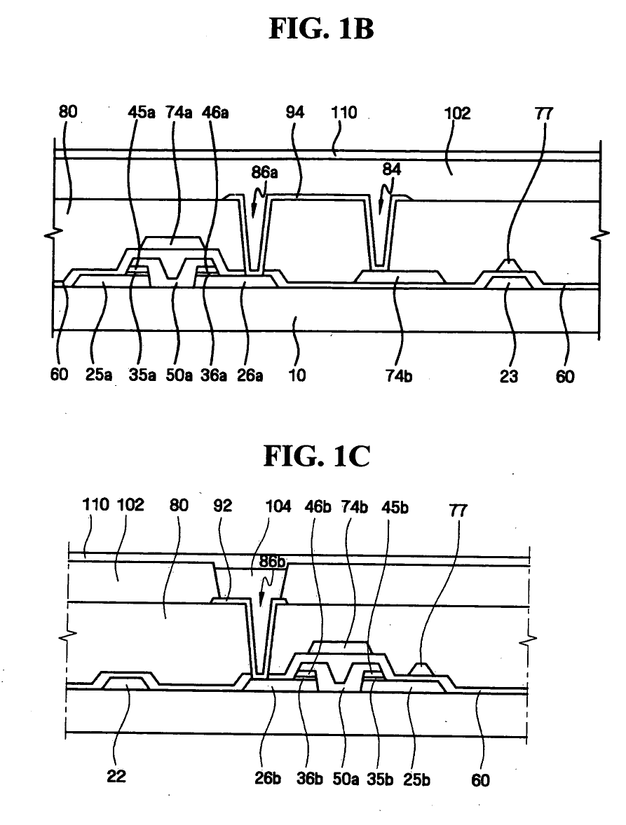

Hereinafter, a thin film transistor (TFT) substrate according to an embodiment of the present invention will be described with reference to the accompanying drawings. FIG. 1A is a layout view of a thin film transistor (TFT) substrate according to an embodiment of the present invention, and FIGS. 1B and 1C are sectional views cut along a line B-B′ and a line C-C′ of FIG. 1A.

As shown in FIGS. 1A through 1C, data interconnection lines 22, 23, 25a, 25b, 26a, and 26b are formed on an insulating substrate 10 made of transparent glass. The data interconnection lines 22, 23, 25a, 25b, 26a, and 26b include a data line 22 extending in a column direction and transmitting a data signal, a driving voltage line 23 formed adjacent to the data line 22 in a column direction and supplying a driving voltage, a first source electrode 25a protruding in a row direction as a branch of the data line 22, a first drain electrode 26a spaced apart from the first source electrode 25a, a second source electrode 25b protruding in a row direction as a branch of the driving voltage line 23, and a second drain electrode 26b spaced apart from the second source electrode 25b.

The data line 22 may have an end portion (not shown) expanded to be easily connected to another layer or an external device. When a data driving circuit generating a data signal is integrated on the substrate 10, the data line 22 may be directly connected to the data driving circuit. The first source electrode 25a connected to the data line 22 serves as an input electrode to a first TFT, receiving the data signal applied to the data line 22, and the first drain electrode 26a serves as an output electrode.

The driving voltage line 23 is adjacent to the data line 22 and extends mainly in a longitudinal direction. The second source electrode 25b connected to the driving voltage line 23 serves as an input electrode applying a driving voltage to a second TFT and the second drain electrode 26b opposite to the second source electrode 25b serves as an output electrode.

The data interconnection lines 22, 23, 25a, 25b, 26a, 26b may include a single layer preferably made of Al, Cu, Ag, Mo, Cr, Ti, Ta, or alloys thereof. Alternatively, the data interconnection lines 22, 23, 25a, 25b, 26a, 26b may have a multi-layered structure including two different conductive films (not shown) having different physical properties. In this case, one of the conductive films is preferably made of a refractory metal such as Mo, Cr, Ti, Ta or alloys thereof, and the other film is preferably made of a low resistivity metal such as Al, Ag, Cu or alloys thereof for reducing signal delay or voltage drop. In addition, a conductive film made of the refractory metal may further be formed on and beneath the conductive film containing Al, Ag or Cu, but the invention is not limited thereto. An example of combination of the two films is a triple layer of Mo/Al/Mo.

Ohmic contact layers 35a, 36a, 35b, and 36b are formed on the first source electrode 25a, the first drain electrode 26a, the second source electrode 25b, and the second drain electrode 26b, respectively. The ohmic contacts may be made of silicide or n+ hydrogenated amorphous silicon doped with high concentration n-type impurity. The ohmic contacts 35a, 36a, 35b, 36b interposed between the underlying source/drain electrodes 25a, 25b, 26a, 26b and the overlying intermediate layers 45a, 46a, 45b and 46b reduce the contact resistance between the electrodes and the intermediate layers. The thickness of each of the ohmic contact layers 35a, 36a, 35b, and 36b may be in a range of about 300-600 Å.

Intermediate layers 45a, 46a, 45b, and 46b having substantially the same shape as the ohmic contact layers 35a, 36a, 35b, and 36b are formed on the ohmic contact layers 35a, 36a, 35b, and 36b. The intermediate layers may comprise amorphous silicon and crystalline silicon. The intermediate layers 45a, 46a, 45b, and 46b are formed continuously after forming the ohmic contact layer 35a, 36a, 35b, and 36b in the same process which prevents foreign materials from being interposed to prevent the electrical characteristics of the TFT from being changed by foreign substances that could accumulate on the interfaces between the intermediate layers 45a, 46a, 45b, and 46b and the ohmic contact layers 35a, 36a, 35b, and 36b if they were not formed continuously. This avoids a threshold voltage shifts from occurring. According to the present invention, the intermediate layers are formed continuously with the ohmic contact layers, so there is little or no likelihood that the ohmic contact layers will be exposed to the air.

Semiconductor layers 50a and 50b are formed on the intermediate layers 45a, 46a, 45b, and 46b such that they cover the intermediate layers 45a, 46a, 45b, and 46b, as well as the space between the first source electrode 25a and the first drain electrode 26a, and the space between the second source electrode 25b and the second drain electrode 26b. The first semiconductor layer 50a is connected to the first source electrode 25a and the first drain electrode 26a through the first ohmic contact layers 35a and 36a and the first intermediate layers 45a and 46a. The second semiconductor layer 50b is connected to the second source 25b and the second drain electrode 26b through the second ohmic contact layers 35b and 36b and the second intermediate layers 45b and 46b.

The semiconductor layers 50a and 50b may comprise amorphous silicon, microcrystalline silicon, or polycrystalline silicon. In an embodiment, the channel portion (i.e., the portion comprising regions within a certain proximity to the gate insulating layer 60) is made of microcrystalline silicon, nanocyrstalline silicon, or polycrystalline silicon. To attain high conductivity and rapid response, it is preferable that there be a high crystalline silicon such as microcrystalline silicon, as well as a high ratio of crystalline silicon to amorphous silicon by volume. In addition, the concentration of nanocyrstalline silicon, or polycrystalline silicon preferably increases towards upper portions of the semiconductor layers 50a and 50b where channels are formed, i.e., portions of the semiconductor layers 50a and 50b within a certain proximity of the gate insulating layer 60.

A foreign substance such as silicon oxide may exist in the interfaces between the intermediate layers 45a, 46a, 45b, and 46b and the semiconductor layers 50a and 50b. However, contact characteristics between the intermediate layers 45a, 46a, 45b, and 46b and the semiconductor layers 50a and 50b are not greatly affected by the foreign substance because the foreign substance is formed in the contact face between layers formed of materials of the same group. This contrasts with the situation where the foreign substance is formed directly on the ohmic contact layers 35a, 36a, 35b, and 36b. This results in little change to the electrical characteristics of the TFT, and results in insignificant threshold voltage shifts.

The gate insulating layer 60 made of silicon nitride or silicon oxide is formed on the semiconductor layers 50a and 50b.

Gate interconnection lines 72, 74a, 74b, and 77 are formed on the gate insulating layer 60.

The gate interconnection lines 72, 74a, 74b, and 77 include a gate line 72 extending in a row column and intersecting the data line 22 to define pixels, a first gate electrode 74a protruding from the gate line 72 in a column direction, a storage electrode 77 overlapping with the driving voltage line 23 and extending in a column direction, and a second gate electrode 74b connected to the storage electrode 77, bent to the left from an end portion of one side of the storage electrode 77, and then bent to the upper direction to be parallel with the storage electrode 77.

A gate signal is applied to the gate line 72 and an end portion (not shown) of the gate line 72 may be expanded to be easily connected to other layers or an external device. The storage electrode 77 overlaps with the driving voltage line 23 to form a storage capacitor.

In this case, the gate interconnection lines 72, 74a, 74b and 77 may be made of Al, Ag, Cu or alloys thereof. In addition, the gate interconnection lines 72, 74a, 74b and 77 may have a multi-layered structure including two different conductive films (not shown) having different physical properties. In this case, one of the conductive films is preferably made of refractory metal such as Mo, Cr, Ti, Ta or alloys thereof, and the other film is preferably made of a low resistivity metal such as Al, Ag, Cu or alloys thereof for reducing signal delay or voltage drop. In addition, a conductive film made of the refractory metal may further be formed on and beneath of the conductive film containing Al, Ag or Cu but the invention is not limited thereto. An example of combination of the two films is a triple layer of Mo/Al/Mo.

The first source electrode 25a, the first drain electrode 26a, the first gate electrode 74a, together with the first semiconductor layer 50a, the first intermediate layers 45a and 46a, and the first ohmic contact layers 35a and 36a, form a first TFT that is a switching TFT. The second source electrode 25b, the second drain electrode 26b, the second gate electrode 74b, together with the second semiconductor layer 50b, the second intermediate layers 45b and 46b, and the second ohmic contact layers 35b and 36b, form a second TFT that is a driving TFT. Regions of the semiconductor layers 50a and 50b between the source electrodes 25a and 25b and the drain electrodes 26a and 26b disposed within a proximity of the gate insulating layer 60 comprise channel portions. According to the present invention, these channel portions contain a high ratio of crystalline silicon to amorphous silicon by volume, resulting in improved electrical characteristics for the TFT.

A passivation layer 80 is formed on the gate interconnection lines 72, 74a, 74b, and 77 and the gate insulating layer 60. The passivation (protective) layer 80 is preferably made of an inorganic insulator such as silicon nitride or silicon oxide, a photosensitive organic material having a good flatness characteristic, or a low dielectric insulating material such as a-Si:C:O and a-Si:O:F formed by plasma enhanced chemical vapor deposition (PECVD). An organic material with a photosensitive characteristic may be used for the passivation layer 80 to simplify the process.

A contact hole 84 exposing the second gate electrode 74b is formed on the passivation layer 80 and contact holes 86a and 86b are formed through the gate insulating layer 60 to expose the first drain electrode 26a and the second drain electrode 26b.

A pixel electrode 92 made of a transparent conductive material such as ITO (indium tin oxide) or IZO (indium zinc oxide) or a material having superior reflectivity such as aluminum (or an alloy thereof) or silver (or an alloy thereof) and a connection member 94 are formed on the passivation layer 80.

The pixel electrode 92 is physically and electrically connected to the second drain electrode 26b via the contact hole 86b and the connection member 94 is connected to the first drain electrode 26a and the second gate electrode 74b via the contact holes 86a and 84, thereby electrically connecting the first drain electrode 26a to the second gate electrode 74b.

A barrier rib 102 may be formed on the passivation layer 80 where the pixel electrode 92 and the connection member 94 are formed. The barrier rib 102 surrounds the edge of the pixel electrode 92 like a bank to define a space within which organic light emitting layer 104 is formed. Barrier rib 102 is made of an organic or inorganic insulating material.

An organic light emitting layer 104 is formed in the opening of the pixel electrode 92. The organic light emitting layer 104 may have a multi-layered structure of a light emitting layer (not shown) and supplementary layers for improving the light emitting efficiency of the light emitting layer. An electron transport layer (not shown) and a hole transport layer (not shown) for balancing electrons and holes and an electron injection layer (not shown) and a hole injection layer (not shown) for improving the injection of electrons and holes may be formed in the supplementary layers.

A common electrode 110 is formed on the barrier rib 102 and the organic light emitting layer 104. A common voltage is applied to the common electrode 110 and the common electrode 110 may be made of a material having superior reflectivity such as aluminum (or an alloy thereof) or silver (or an alloy thereof) or a transparent conductive material such as ITO or IZO. If the pixel electrode 92 is opaque, the common electrode 110 can be made of a transparent material, causing light to be emitted from the organic light emitting layer 104 upwards with respect to FIGS. 1B and 1C. If the pixel electrode 92 is transparent, the common electrode 110 can be made of an opaque material, causing light to be emitted from the organic light emitting layer 104 downwards with respect to FIGS. 1B and 1C.

The TFT substrate according to an embodiment of the present invention can be applied to an organic EL display.

Hereinafter, a method for manufacturing a TFT substrate according to an embodiment of the present invention will be described with reference to FIGS. 1A through 1c and FIGS. 2A through 9C.

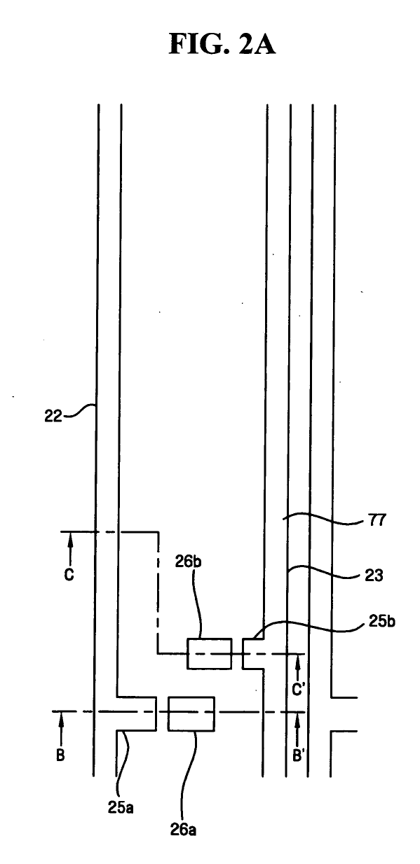

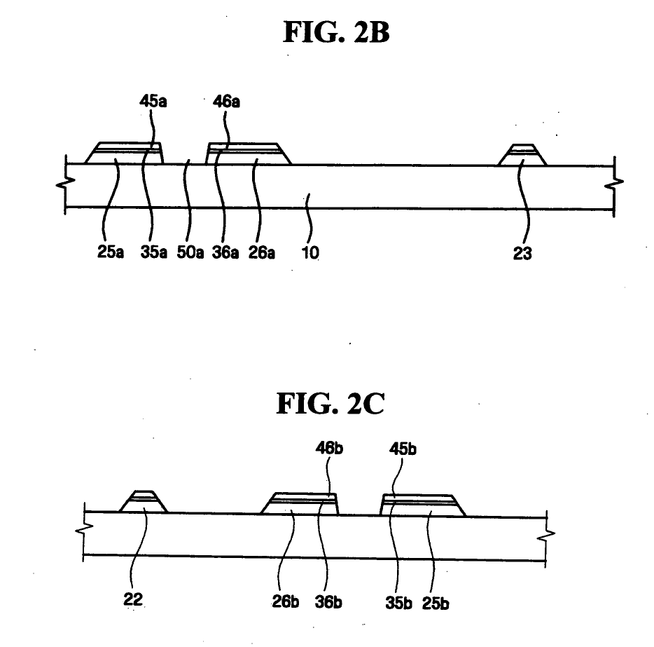

First, referring to FIGS. 2A through 2C, aluminum (Al), copper (Cu), silver (Ag), molybdenum (Mo), chrome (Cr), titanium (Ti), tantalum (Ta), or an alloy thereof is deposited on the insulating substrate 10 to a thickness of about 1000-3000 Å using sputtering or electroless plating, thereby forming a data conductive layer.

Amorphous silicon doped with n+ impurity is deposited to a thickness of 300-600 Å through chemical vapor deposition (CVD), thereby forming an impurity-doped silicon layer that will later be patterned into the ohmic contact layers 35a, 36a, 35b, and 36b. Next, intrinsic amorphous silicon is deposited to a thickness of 300-1000 Å. This layer is referred to as an ‘intermediate silicon layer,’ as distinguished from the lower impurity-doped silicon layer and the upper intrinsic silicon layer to be formed in a subsequent process. The intermediate silicon layer will be patterned later to form the intermediate layers 45a, 46a, 45b, and 46b. The intermediate silicon layer may be formed through CVD, which will be described in detail later.

To pattern the impurity-doped silicon layer and the intermediate silicon layer, a photoresist pattern defining a data interconnection line is formed on the intermediate silicon layer. The intermediate silicon layer, the impurity-doped silicon layer, and the data conductive layer are then sequentially etched using the photoresist pattern as an etching mask. The intermediate silicon layer and the impurity-doped silicon layer may be dry etched simultaneously using the same etching gas, because their etching selectivity is low. The data conductive layer may be wet etched. These steps form the data interconnection lines 22, 23, 25a, 25b, 26a, and 26b including the data line 22 extending in a column direction and transmitting a data signal, the driving voltage line 23 extending adjacent to the data line 22 in a column direction and supplying a driving voltage, the first source electrode 25a protruding in a row direction as a branch of the data line 22, the first drain electrode 26a spaced apart from the first source electrode 25a, the second source electrode 25b protruding in a row direction as a branch of the driving voltage line 23, and the second drain electrode 26b spaced apart from the second source electrode 25b. The patterned etching also forms ohmic contact layers 35a, 36a, 35b, and 36b and intermediate layers 45a, 46a, 45b, and 46b according to the same pattern as the underlying data interconnection lines 22, 23, 25a, 25b, 26a, and 26b.

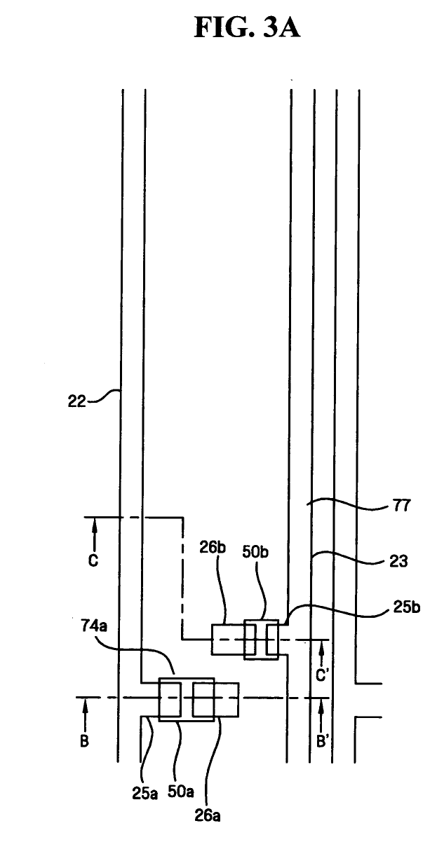

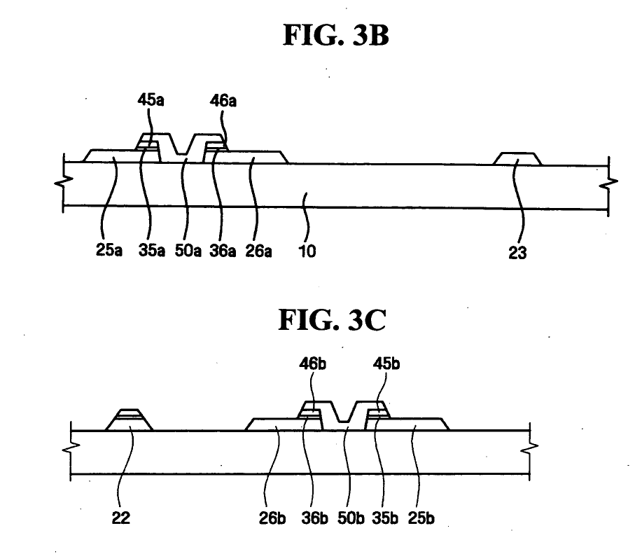

Referring to FIGS. 3A through 3C, to form the semiconductor layers 50a and 50b including channel portions, intrinsic silicon is deposited to a thickness of about 500-2000 Å on the insulating substrate 10. The intrinsic silicon layer may be formed using CVD. More specifically, a deposition target object is placed into a reaction chamber, and a power source applies power to the reaction chamber. Here, the deposition target object comprises the insulating substrate 10 where the data interconnection lines 22, 23, 25a, 25b, 26a, and 26b, the ohmic contact layers 35a, 36a, 35b, and 36b, and the intermediate layers 45a, 46a, 45b, and 46b. Then, a mixture of a gas including silicon such as SiH₄, SiH₂Cl₂, or SiH₂F₂ and a hydrogen gas is supplied to the reaction chamber. During this time, the internal temperature of the reaction chamber is maintained at about 250-400□. Under the conditions described above, the mixture within the reaction chamber is activated and is then deposited on the deposition target object through a chemical reaction.

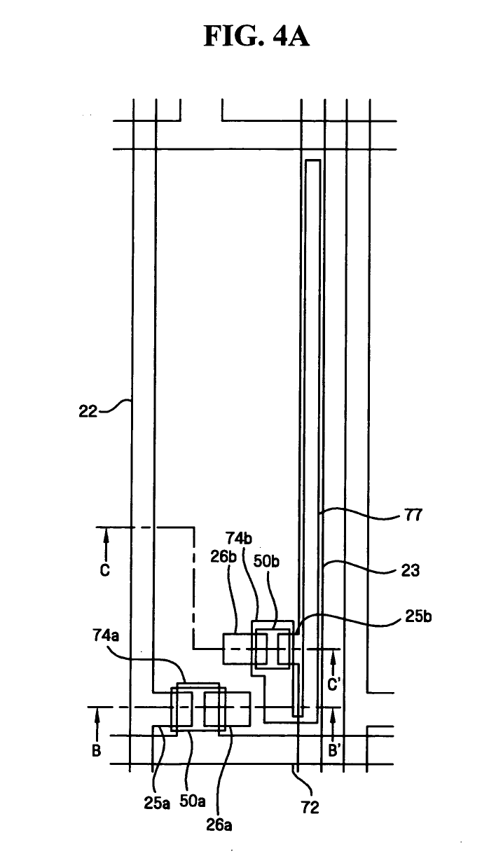

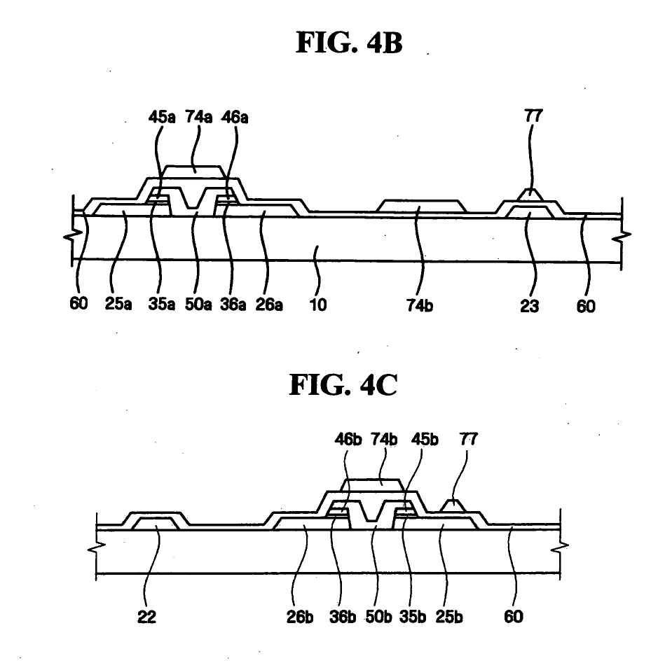

To attain a channel portion with improved electrical characteristics, it is preferable that the intrinsic silicon described above be deposited in the form of crystalline silicon rather than amorphous silicon. Crystalline silicon includes microcrystalline silicon, nanocyrstalline silicon, and polycrystalline silicon. To crystallize amorphous silicon, it is preferable that deposition speed be low, for example, 1 Å/sec or less. This deposition speed can be obtained by setting the ratio of silicon gas (such as SiH₄, SiH₂Cl₂, or SiH₂F₂) to hydrogen gas in the mixture to be 0.05 or less, while simultaneously applying a power of 100 mW/cm² or less to the reaction chamber. Under these conditions, the deposited silicon will be initially amorphous, but become increasingly crystalline in nature as the deposition progresses. As a result, the semiconductor layers 50a and 50b will be predominantly crystalline in the regions adjacent to the gate insulating layer 60 (later to be formed, see FIGS. 4B and 4C), also known as the “channel regions.” This improves the electrical characteristics of the channel regions. To form a semiconductor layer having crystalline silicon to a thickness of about 500-2000 Å, the deposition may continue for about 500-2000 seconds at a speed of 1 Å/sec.

Note that the technique of forming crystalline silicon described above with respect to the semiconductor layers 50a and 50b may also be applied to the formation of intermediate layers 45a, 46a, 45b, and 46b earlier described with reference to FIGS. 2B and 2C. This will improve the electrical characteristics of the intermediate layers. In an embodiment, the deposition time may be in a range of 300-1000 seconds to achieve a thickness 300-1000 Å for the intermediate layers 45a, 46a, 45b, and 46b.

Next, to pattern the semiconductor layers 50a and 50b, a photoresist pattern is formed on the intrinsic silicon layer. The silicon layer is etched using the photoresist pattern as an etching mask. Portions of the intermediate layers 45a, 46a, 45b, and 46b, and the ohmic contact layers 35a, 36a, 35b, and 36b not covered by the etched semiconductor layers 50a and 50b are also etched. The intrinsic silicon layer, the intermediate layers 45a, 46a, 45b, and 46b, and the ohmic contact layers 35a, 36a, 35b, and 36b may be dry etched simultaneously using the same etching gas. Thus, a semiconductor layer pattern including crystalline silicon is formed in such a way to cover the intermediate layers 45a, 46a, 45a, and 46b and spaces between the source electrodes 25a and 25b and the drain electrodes 26a and 26b on the insulating substrate 10.

Referring to FIGS. 4A through 4C, silicon nitride or silicon oxide is deposited on the insulating substrate 10 thereby forming the gate insulating layer 60. Next, aluminum (Al), copper (Cu), silver (Ag), molybdenum (Mo), chrome (Cr), titanium (Ti), tantalum (Ta), or an alloy thereof is deposited on the gate insulating layer 60 using sputtering, and is then patterned, thereby forming the gate interconnection lines 72, 74a, 74b, and 77. These include the gate line 72 extending in a row direction and intersecting the data line 22 to define pixels, the first gate electrode 74a protruding from the gate line 72 in a column direction, the storage electrode overlapping with the driving voltage line 23 and extending in a column direction, and the second gate electrode 74b connected to the storage electrode 77, bent to the left from an end portion of one side of the storage electrode 77, and then bent to the upper direction to be parallel with the storage electrode 77.

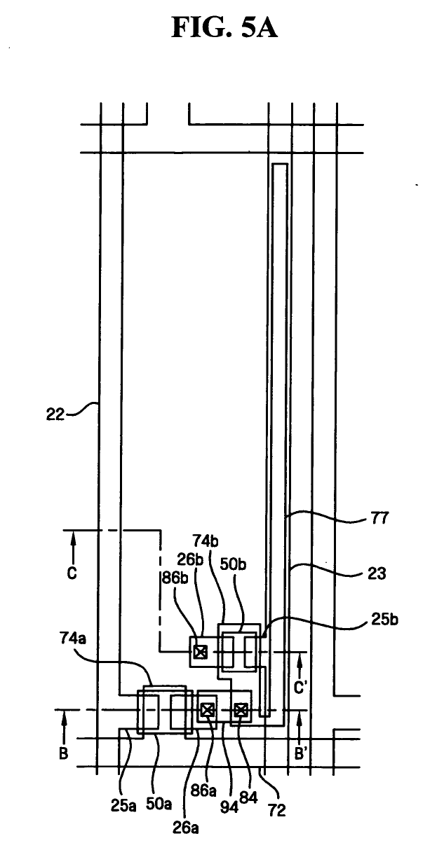

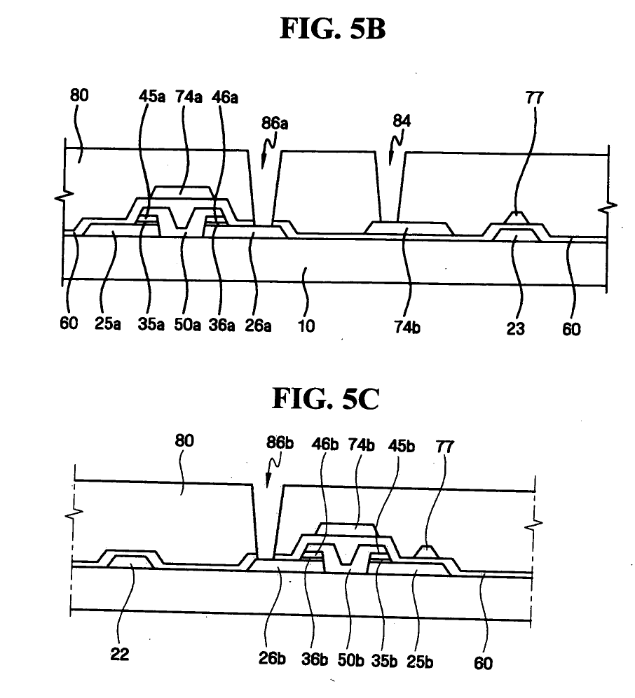

Referring to FIGS. 5A through 5C, the passivation layer 80 made of an inorganic insulating material or an organic insulating material is formed on the gate insulating layer 60. Photolithography is then performed on the passivation layer 80, thereby forming the contact hole 84 exposing the second gate electrode 74b and the contact holes 86a and 86b penetrating the gate insulating layer 60 to expose the first drain electrode 26a and the second drain electrode 26b.

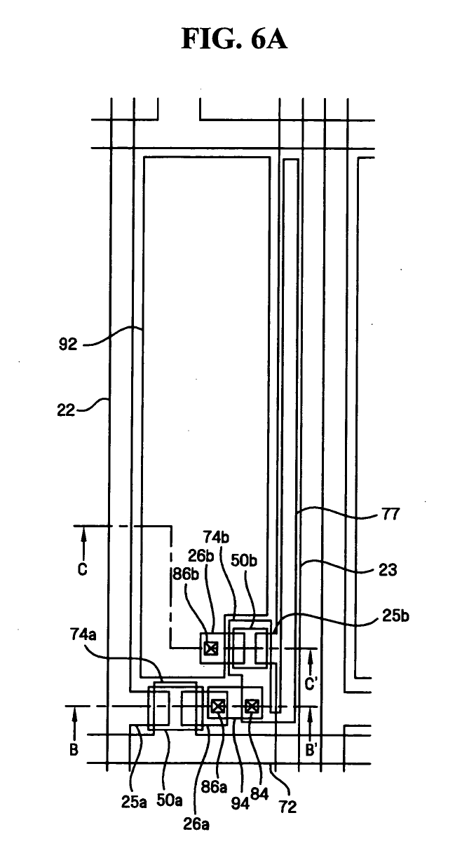

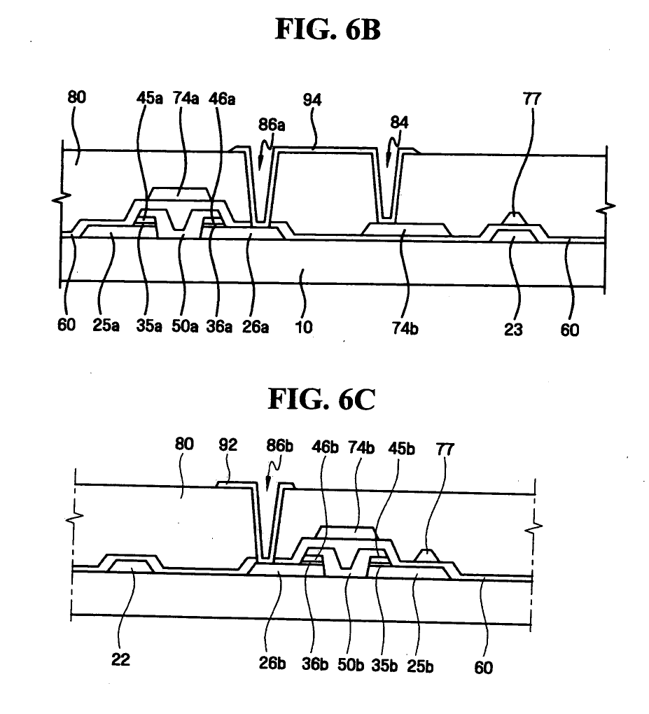

Referring to FIGS. 6A through 6C, a transparent conductive material such as ITO or IZO or a metal having superior reflectivity such as aluminum (or an alloy thereof) or silver (or an alloy thereof) is deposited on the passivation layer 80 through sputtering and is then patterned, thereby forming the pixel electrode 92 and the connection member 94.

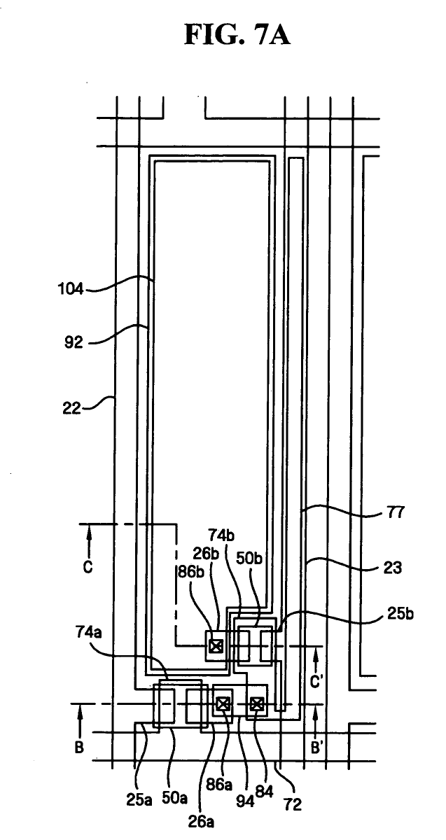

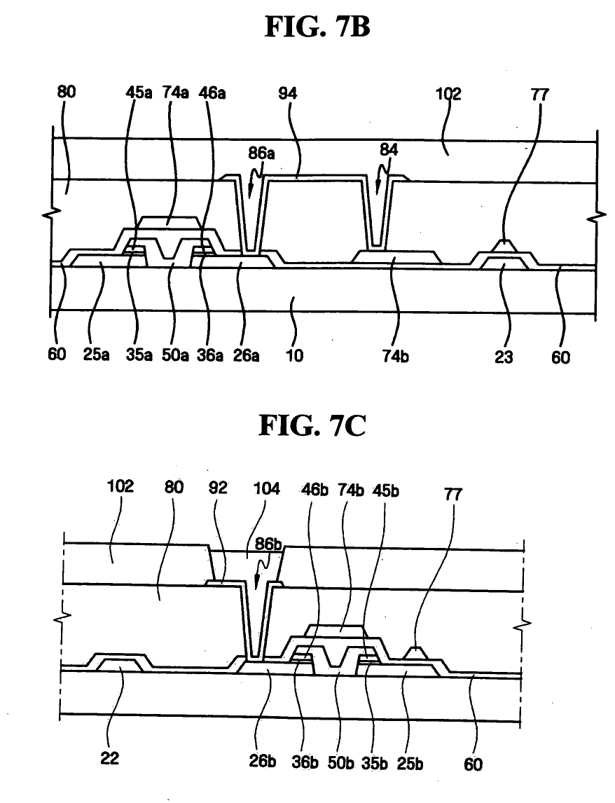

Referring to FIGS. 7A through 7C, an organic layer including a black pigment is coated and patterned, thereby forming the barrier rib 102 defining the opening on the pixel electrode 92. The organic light emitting layer 104 is formed in each opening using inkjet printing.

Finally, as shown in FIGS. 1A through 1C, a metal having superior reflectivity such as aluminum (or an alloy thereof) or silver (or an alloy thereof) or a transparent conductive material such as ITO or IZO is deposited on the barrier rib 102 and the organic light emitting layer 104, thereby forming the common electrode 110.

In the current embodiment of the present invention, crystalline silicon is formed in the semiconductor layers 50a and 50b and crystalline silicon may be or may not be formed in the intermediate layers 45a, 46a, 45b, and 46b, but the present invention is not limited thereto. In one embodiment, when the semiconductor layers 50a and 50b include amorphous silicon instead of crystalline silicon, foreign substances such as an oxide of silicon are not formed on the ohmic contact layers 35a, 36a, and 35b, and 36b because the intermediate layers 45a, 46a, 45b, and 46b are formed continuously with the ohmic contact layers 35a, 36a, 35b, and 36b, thereby improving the electrical characteristics.

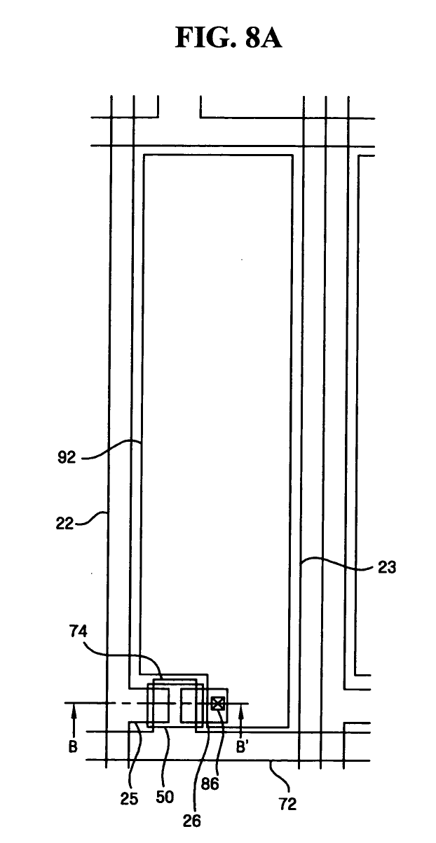

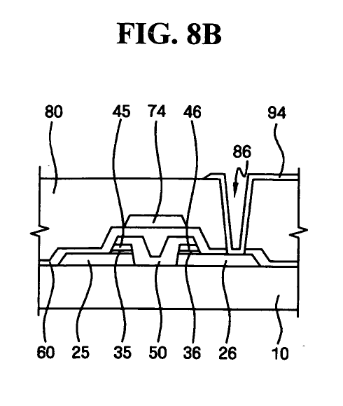

Although the TFT substrate and the method for manufacturing the same according to the present invention are applied to an organic EL display in the above description, they may also be applied to an LCD. An LCD embodiment where the present invention will be described with reference to FIGS. 8A and 8B. To avoid repetitive explanation, a description will be focused on a difference between the two embodiments. FIG. 8A is a layout view of a TFT substrate according to an LCD embodiment of the present invention, and FIG. 8B is a sectional view cut along a line B-B′ of FIG. 8A.

As shown in FIGS. 8A and 8B, a TFT substrate according to an embodiment of the present invention includes only one TFT as a switching device in a pixel. Here, components of the TFT are similar to those of the first TFT shown in FIG. 1B, with certain differences. Like in FIG. 1B, FIG. 8B shows a pixel electrode 94 that is directly connected to the drain electrode 26 via the contact hole 86. In contrast to FIG. 1B, however, a barrier rib or an organic light emitting layer is not formed on the passivation layer 80 in FIG. 8B. Furthermore, a pixel electrode 94 and a common electrode are formed on different substrates. In view of the descriptions given above for manufacturing a TFT substrate according to the present invention, other embodiments of the present invention will be obvious to those skilled in the art.

The TFT substrate according to another embodiment of the present invention can also be applied to a reflective LCD.

While the present invention has been particularly shown and described with reference to exemplary embodiments thereof, it will be understood by those of ordinary skill in the art that various changes in form and details may be made therein without departing from the spirit and scope of the present invention as defined by the following claims. Therefore, it is to be understood that the above-described embodiments have been provided only in a descriptive sense and will not be construed as placing any limitation on the scope of the invention.

What is claimed is:

1. A method for manufacturing a thin film transistor (TFT) substrate, the method comprising:
forming on a substrate a conductive layer, an impurity-doped silicon layer, and an intermediate layer, wherein the intermediate layer comprises intrinsic silicon;
patterning the intermediate layer, the impurity-doped silicon layer, and the conductive layer to form a data line, a source electrode, a drain electrode, ohmic contact portions, and intermediate portions, wherein an ohmic contact portion and an intermediate portion are on the source electrode, and an ohmic contact portion and an intermediate portion are on the drain electrode;
forming an intrinsic silicon layer on the substrate; and
patterning the intrinsic silicon layer to form a semiconductor layer forming channel portion between the source electrode and the drain electrode, and a contact portion on the intermediate portion.

2. The method of claim 1, wherein the formation of the intermediate layer follows immediately after the formation of the impurity-doped silicon layer.

3. The method of claim 1, wherein forming the intermediate layer comprises performing deposition at a speed of 1 Å/sec or less.

4. The method of claim 1, wherein forming the intermediate layer comprises performing deposition wherein the ratio of a silicide to a hydrogen gas by volume is 0.05 or less.

5. The method of claim 4, wherein the silicide is selected from the group consisting of SiH₄, SiH₂Cl₂, and SiH₂F₂.

6. The method of claim 1, wherein forming the intermediate layer is performed while a power of 100 mW/cm² or less is applied to a reaction chamber.

7. The method of claim 1, wherein the intermediate silicon layer includes crystalline silicon.

8. The method of claim 7, wherein a ratio of crystalline silicon to amorphous silicon increases towards an upper portion of the intermediate silicon layer.

9. The method of claim 1, wherein patterning the intermediate layer, the impurity-doped silicon layer, and the data conductive layer comprises etching using a single photoresist pattern.

10. The method of claim 9, wherein patterning the intermediate layer and the impurity-doped silicon layer comprises dry etching using the same etching gas.

11. The method of claim 1, wherein forming the intrinsic silicon layer comprises performing deposition at a speed of 1 Å/sec or less.

12. The method of claim 1, wherein forming the intrinsic silicon layer comprises performing deposition wherein the ratio of a silicide to a hydrogen gas is 0.05 or less.

13. The method of claim 12, wherein the silicide is selected from the group consisting of SiH₄, SiH₂Cl₂, and SiH₂F₂.

14. The method of claim 1, wherein forming the intrinsic silicon layer comprises applying a power of 100 mW/cm² or less to a reaction chamber.

15. The method of claim 1, wherein the semiconductor layer comprises crystalline silicon.

16. The method of claim 15, wherein a ratio of crystalline silicon to amorphous silicon increases towards an upper portion of the semiconductor layer.

17. The method of claim 1, further comprising the steps of, after forming the semiconductor layer:
etching the intermediate layer and the ohmic contact layer that are not covered by the semiconductor layer to expose the data interconnection lines;
forming a gate insulating layer on the semiconductor layer;
forming a gate conductive layer on the gate insulating layer to form a gate interconnection line including a gate electrode on a channel portion of the semiconductor layer;
forming a passivation layer on the gate interconnection line; and
forming a pixel electrode electrically connected to the drain electrode on the passivation layer.

18. The method of claim 17, further comprising, after forming the pixel electrode:
forming a barrier rib and an organic light emitting layer on the pixel electrode; and
forming a common electrode on the organic light emitting layer.

19. A thin film transistor (TFT) substrate manufactured by the method of claim 1.

20. A thin film transistor (TFT) substrate comprising:
data lines including a source electrode formed on a substrate and a drain electrode separated from the source electrode;
an ohmic contact layer formed on the source electrode and the drain electrode, wherein the ohmic contact layer comprises impurity-doped silicon;
an intermediate layer formed on the ohmic contact layer, wherein the intermediate layer includes intrinsic silicon; and
a semiconductor layer comprising a portion on the intermediate layer and a channel portion between the source electrode and the drain electrode.
